(19) United States
(12) Patent Application Publication
(10) Pub. No.: US 2009/0008796 A1
(43) Pub. Date: Jan. 8, 2009

(54) COPPER ON ORGANIC SOLDERABILITY PRESERVATIVE (OSP) INTERCONNECT

(75) Inventors: Kian Teng Eng, Singapore (SG); Wolfgang Johannes HETZEL, Nattheim (DE); Werner Josef REISS, Feilnbach (DE); Florian AMMER, Ergoldsbach (DE); Yong Chuan KOH, Singapore (SG); Jimmy SIAT, Singapore (SG)

Correspondence Address: SUGHRUE MION, PLLC, 2100 PENNSYLVANIA AVENUE, N.W., SUITE 800, WASHINGTON, DC, 20037, US

(73) Assignees: United Test and Assembly Center Ltd., Singapore (SG); Qimonda

(21) Appl. No.: 11/965,252

(22) Filed: Dec. 27, 2007

Related U.S. Application Data
(60) Provisional application No. 60/882,710, filed on Dec. 29, 2006.
(60) Provisional application No. 60/951,018, filed on Jul. 20, 2007.

(51) Int. Cl. H01L 23/49; H01L 21/44

(52) U.S. Cl. 257/777; 438/617; 257/E23.024; 257/E21.476

(57) ABSTRACT

Provided is a semiconductor package, and a method for constructing the same, including a first substrate, a first semiconductor chip attached to the first substrate, and a first copper wire. At least one of the first substrate and the first semiconductor chip has an Organic Solderability Preservative (OSP) material coated on at least a portion of one surface, and the first copper wire is wire bonded through the OSP material to the first substrate and the first semiconductor chip.

### CROSS-REFERENCE TO RELATED APPLICATIONS

This application claims priority from U.S. Provisional Application No. 60/882,710 filed on Dec. 29, 2006 and U.S. Provisional Application No. 60/951,018 filed on Jul. 20, 2007, the disclosures of which are incorporated herein by reference.

### BACKGROUND OF INVENTION

1. Field of Invention

Apparatuses and methods consistent with the present invention relate to Copper (Cu) wire bonding through Organic Solderability Preservative (OSP) material that coats a substrate and/or through OSP material that coats a chip bond pad.

2. Description of the Related Art

Wire bonding is generally a means of electrical connection between a semiconductor chip and a substrate. The substrate may, for example, be a printed circuit board (PCB) or a lead frame. Wire bonding typically involves using gold (Au) wire, aluminum (Al) wire, Cu wire, silver (Ag) wire, or a combination of alloy wire to form the electrical connection.

Au wire is commonly used as a form of electrical connection between the semiconductor chip and the substrate. Typically, the Au wire is bonded to an Al bond pad formed on the chip at one end, and bonded to the substrate at the other end. During bonding, the Au and Al inter-diffuse into each other and may result in high electrical resistance and high heat generation. This may then lead to low bonding reliability and device performance. Also, the poor heat dissipation characteristic of gold materials may cause overheating in the IC assembly.

Furthermore, Au materials have low tensile strength and may result in poor wire sagging, poor wire sweeping performance, poor wire loop profile and instability for long wires, during packing encapsulation. Also, in Au wire bonding, a process of Ni and Au coating on the substrate is required in order to achieve an acceptable electrical connection between the Au wire and the substrate.

Another problem that may occur in wire bonding is that the bond pad surface on the chip or the lead finger surface on the substrate may have oxidized material coated thereon, which may decrease bonding reliability. For example, when wire bonding to a Cu bond pad, the Cu bond pad oxidizes readily to form a layer of oxide on the bond pad surface. The oxide layer prevents effective bonding between the wire and the Cu bond pad.

There is therefore a need to provide apparatuses and methods that can ameliorate the disadvantages as described above.

### SUMMARY OF THE INVENTION

Exemplary embodiments of the present invention overcome the above disadvantages and other disadvantages not described above. Also, the present invention is not required to overcome the disadvantages described above, and an exemplary embodiment of the present invention may not overcome any of the problems described above.

According to an aspect of the present invention, there is provided semiconductor package including a first substrate; a first semiconductor chip attached to the first substrate, wherein at least one of the first substrate and the first semiconductor chip has an OSP material coated on at least a portion of one surface; and a first copper wire that is wire bonded through the OSP material to the at least one of the first substrate and the first semiconductor chip.

The first substrate may include a lead finger, and the first copper wire may be wire bonded to the lead finger.

The lead finger may be coated with the OSP material.

The lead finger may include at least one of copper, aluminum, and silver.

The first semiconductor chip may include a bond pad, and the first copper wire may be wire bonded to the bond pad.

The bond pad may be coated with the OSP material.

The bond pad may include at least one of copper, aluminum, and silver.

The semiconductor package may further include a second semiconductor chip attached to the first substrate or to the first semiconductor chip, wherein at least one of the first substrate and the second semiconductor chip has the OSP material coated on at least a portion of one surface; and a second copper wire that is wire bonded through the OSP material to the at least one of the first substrate and the second semiconductor chip.

The first semiconductor chip and the second conductor chip may be disposed on opposite sides of the first substrate.

The semiconductor package may further include a second substrate having the OSP material coated on at least a portion of one surface; and a third copper wire that is wire bonded through the OSP material of the first substrate to a lead finger of the first substrate and through the OSP material of the second substrate to a lead finger of the second substrate, wherein the lead finger comprises at least one of copper, aluminum, and silver.

The second conductor chip may be stacked on the first semiconductor chip.

The semiconductor package may further include a second substrate having the OSP material coated on at least a portion of one surface; and a third copper wire that is wire bonded to the second semiconductor chip and is wire bonded through the OSP material of the second substrate to a lead finger of the second substrate, wherein the first semiconductor chip is disposed on the first substrate and on the second substrate, and wherein the lead finger includes at least one of copper, aluminum, and silver.

The semiconductor package may further include a third semiconductor chip, wherein at least one of the first substrate and the third semiconductor chip has the OSP material coated on at least a portion of one surface; and a third copper wire that is wire bonded through the OSP material to the first substrate and the third semiconductor chip, wherein the third semiconductor chip is stacked on the second semiconductor chip, and the second semiconductor chip is stacked on the first semiconductor chip.

With respect to a cross-section view of the semiconductor package, the third semiconductor chip may be wider than the second semiconductor chip, and the second semiconductor chip may be wider than the first semiconductor chip.

With respect to a cross-section view of the semiconductor package, the first semiconductor chip may be wider than the second semiconductor chip, and the second semiconductor chip may be wider than the third semiconductor chip.

The semiconductor package may further include one of a Ball Bond, Stitch Bond, Ribbon Bond, Wedge Bond, and Copper Stud Bond where the copper wire is wire bonded to the substrate.

The semiconductor package may further include one of a Ball Bond, Stitch Bond, Ribbon Bond, Wedge Bond, and Copper Stud Bond where the copper wire is wire bonded to the semiconductor chip.

According to another aspect of the invention, there is provided a method for constructing a semiconductor package, the method including: (a) wire bonding one end of a copper wire to a substrate through an OSP material that is coated on the substrate; and (b) wire bonding an opposite end of the copper wire to a semiconductor chip.

The substrate may include a lead finger; (a) may include wire bonding the copper wire through the OSP material to connect the lead finger to the semiconductor chip; and the lead finger may include at least one of copper, aluminum, and silver.

The lead finger may be coated with the OSP material.

The first semiconductor chip may include a bond pad; (b) may include wire bonding the copper wire to the bond pad; and the bond pad may include at least one of copper, aluminum, and silver.

The bond pad may be coated with the OSP material.

Furthermore, (a) may include forming one of a Ball Bond, Stitch Bond, Ribbon Bond, Wedge Bond, and Copper Stud Bond on the substrate.

Additionally, (b) may include forming one of a Ball Bond, Stitch Bond, Ribbon Bond, Wedge Bond, and Copper Stud Bond on the semiconductor chip.

### BRIEF DESCRIPTION OF THE DRAWINGS

The above and/or other aspects of the present invention will become apparent and more readily appreciated from the following description of the exemplary embodiments, taken in conjunction with the accompanying drawings, in which:

FIG. 1 illustrates a semiconductor package according to an exemplary embodiment of the present invention.

FIG. 2 is an isometric view of the semiconductor package of FIG. 1.

FIG. 3 is an isometric view of a semiconductor package according to another exemplary embodiment of the present invention.

FIG. 4 illustrates a semiconductor package according to another exemplary embodiment of the present invention.

FIG. 5 illustrates a semiconductor package according to another exemplary embodiment of the present invention.

FIG. 6 illustrates a semiconductor package according to another exemplary embodiment of the present invention.

FIG. 7A illustrates a semiconductor package according to another exemplary embodiment of the present invention, and FIG. 7B illustrates copper wires which are wire bonded to lead fingers of the substrate of the semiconductor package of FIG. 7A.

FIG. 8 illustrates a semiconductor package according to another exemplary embodiment of the present invention.

FIG. 9 illustrates a semiconductor package according to another exemplary embodiment of the present invention.

FIGS. 10A and 10B show alternate views of a copper Stud Bump and Stitch On Stud Bump on OSP coated copper, aluminum, and silver lead fingers of an OSP substrate.

FIGS. 11A and 11B show alternate views of a copper Stitch Bond on OSP coated copper, aluminum, and silver lead fingers of an OSP substrate.

FIGS. 12A and 12B show alternate views of a copper Stud Bump and Stitch On Stud Bump on an OSP coated copper and aluminum pads of a semiconductor chip.

FIGS. 13A and 13B show alternate views of a copper Ball Bond on OSP coated copper and aluminum lead fingers of an OSP substrate.

FIGS. 14A and 14B show alternate views of a copper Ball Bond on OSP coated copper and aluminum pads of a semiconductor chip.

FIGS. 15A and 15B show a copper Single Stud and Stack Stud Bump on the OSP coated copper and aluminum bond pads of a semiconductor chip.

FIGS. 16A and 16B show a copper Ball Bond on OSP coated copper and aluminum bond pads as well as on OSP coated lead fingers.

FIG. 17 shows a method of constructing a semiconductor package according to an exemplary embodiment of the present invention.

### DETAILED DESCRIPTION OF EXEMPLARY EMBODIMENTS OF THE INVENTION

Hereinafter, exemplary embodiments of the present invention will be described with reference to the accompanying drawings.

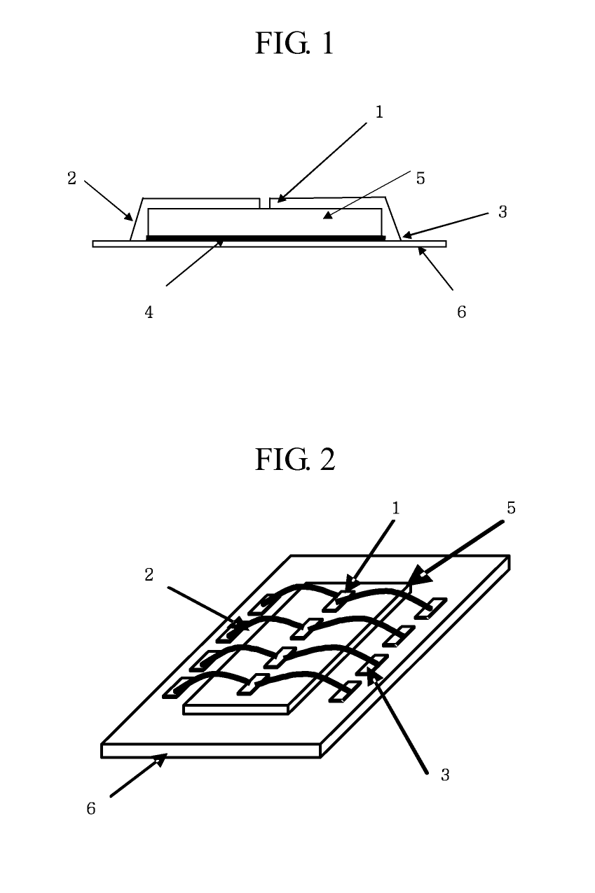

FIG. 1 illustrates a semiconductor package according to an exemplary embodiment of the present invention.

As shown in FIG. 1 the semiconductor package according to an exemplary embodiment of the present invention includes bond pads 1, copper wires 2, lead fingers 3, adhesive material 4, a semiconductor chip 5, and an OSP substrate 6.

The adhesive material 4 is used to provide adhesion between the semiconductor chip 5 and the OSP substrate 6.

The OSP substrate 6 is coated in an OSP material, and the copper wire 2 is wire bonded through the OSP material to a lead finger 3 of the OSP substrate 6. The substrate may be a lead frame material (e.g., Alloy 42, Cu7025, Olin 0194, and other copper alloys), PCB, substrate core material (e.g., BT832, Hitachi E679, Nanya NPG-150), glass panel or ceramic material. The OSP coating on the substrate 6 may be over the entire surface, partially over the surface or on the lead fingers 3. The lead finger 3 or bond pad 1 may comprise copper, aluminum, silver, or other conductive materials. The copper wire 2 is also wire bonded to the bond pad 1 of the semiconductor chip 5, and the bond pad 1 may be coated in the OSP material.

FIG. 2 is an isometric view of the semiconductor package of FIG. 1. As shown in FIG. 2, the copper wire bonding is able to provide an electrical connection for the semiconductor chip 5 with bond pads 1 located at the center or peripheral of the die. The length of copper wires 2 can be varied accordingly with respect to the location of the bond fingers 3 on the OSP substrate 6.

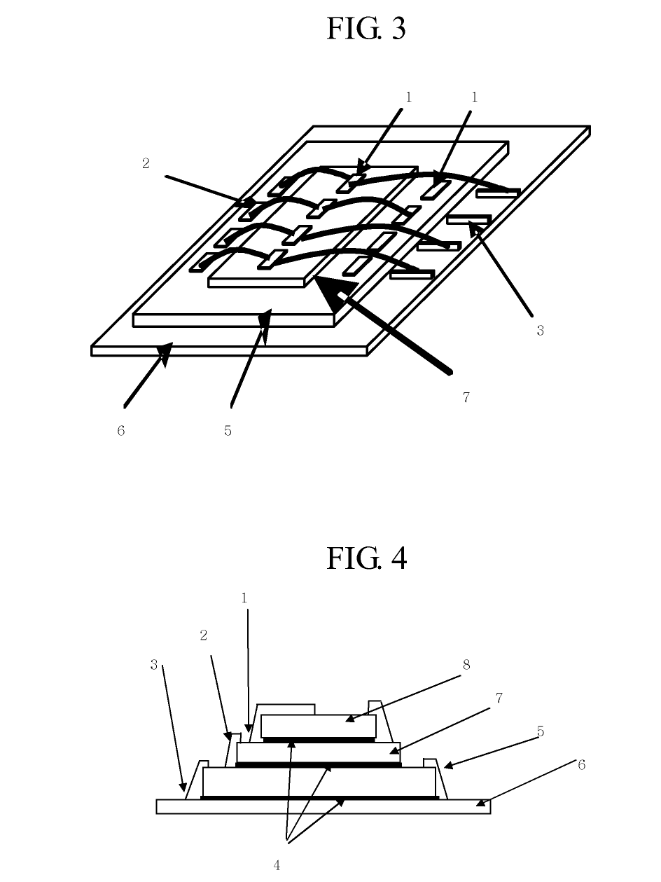

FIG. 3 is an isometric view of a semiconductor package according to another exemplary embodiment of the present invention. As shown in FIG. 3, the semiconductor package may include a second semiconductor chip 7 stacked vertically with semiconductor chip 5. The second semiconductor chip 7 has a plurality of bond pads 1. Copper wire bonding provides an electrical connection between the bond pads 1 of the second semiconductor chip 7 and the bond pads 1 of the semiconductor chip 5. Copper wire bonding also provides an electrical connection between the bond pads 1 of the second semiconductor chip 7 and the lead fingers 3 of the OSP substrate 6. The bond pads 1 of the semiconductor chip 5 and/or the second semiconductor chip 7 may be coated in the OSP material.

FIG. 4 illustrates a semiconductor package according to another exemplary embodiment of the present invention. As shown in FIG. 4, the semiconductor package may include a third semiconductor chip 8 stacked vertically with the second semiconductor chip 7 and the first semiconductor chip 5. Similar to the semiconductor chip 5 and the second semiconductor chip 7, the third semiconductor chip 8 has a plurality of bond pads 1. Copper wire bonding provides an electrical connection between the bond pads 1 of the third semiconductor chip 8 and the bond pads 1 of each of the semiconductor chip 5 and the second semiconductor chip 7. Copper wire bonding also provides an electrical connection between the bond pads 1 of the third semiconductor chip 8 and the lead fingers 3 of the OSP substrate 6. The bond pads 1 of the semiconductor chip 5, the second semiconductor chip 7 and/or the third semiconductor chip 8 may be coated in the OSP material.

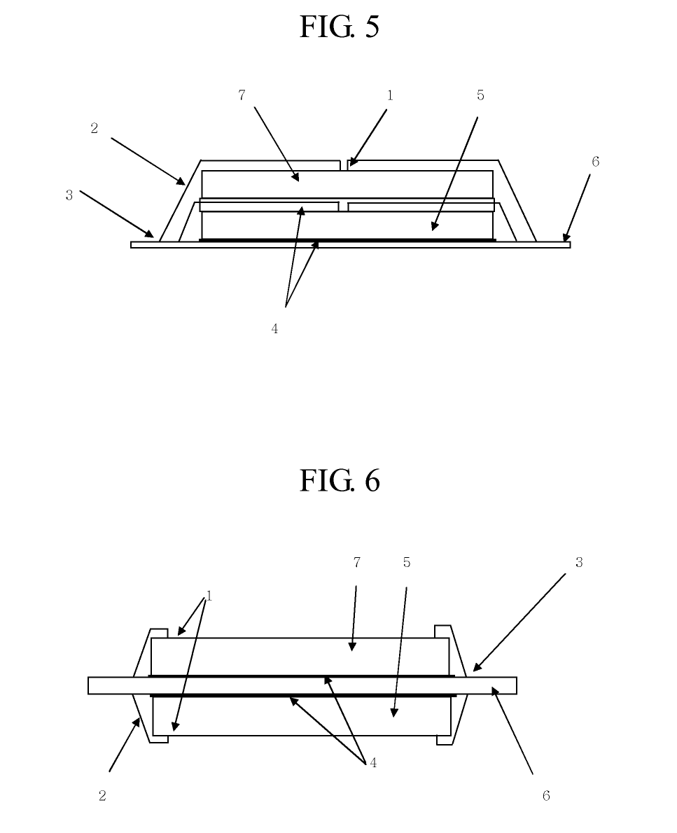

FIG. 5 illustrates a semiconductor package according to another exemplary embodiment of the present invention. As shown in FIG. 5, the second semiconductor chip 7 may be stacked vertically on the semiconductor chip 5. Also, the second semiconductor chip 7 and the semiconductor chip 5 may have approximately the same width with respect to a cross section view of the semiconductor package. The bond pads 1 of the semiconductor chip 5 and/or the second semiconductor chip 7 may be coated in the OSP material.

FIG. 6 illustrates a semiconductor package according to another exemplary embodiment of the present invention. As shown in FIG. 6, the second semiconductor chip 7 and the semiconductor chip 5 may be disposed on opposite sides of the OSP substrate 6. The bond pads 1 of the semiconductor chip 5 and/or the second semiconductor chip 7 may be coated in the OSP material.

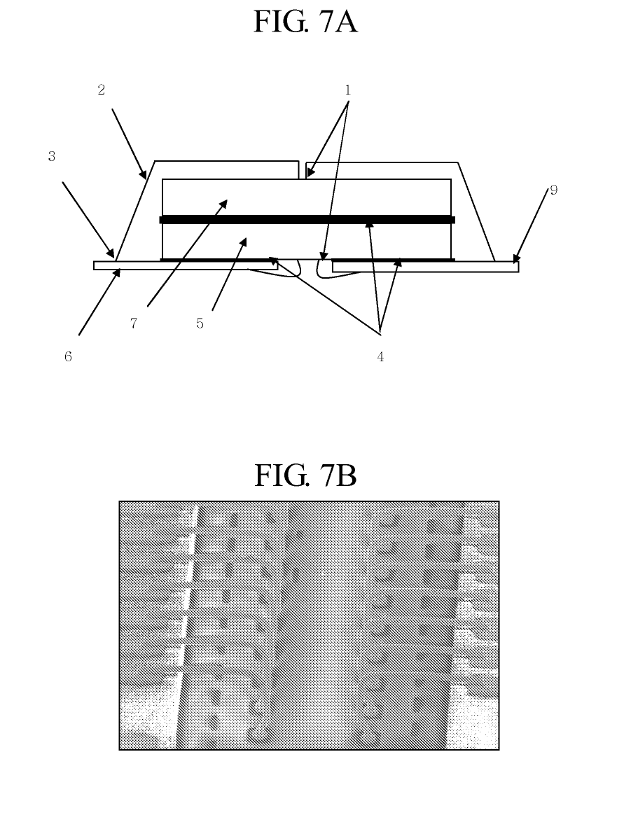

FIG. 7A illustrates a semiconductor package according to another exemplary embodiment of the present invention. As shown in FIG. 7A, the semiconductor package may include a second OSP substrate 9 which is coated in the OSP material. The OSP coating on the second substrate 9 may be over the entire surface, partially over the surface or on lead fingers 3. The semiconductor chip 5 is arranged so that a bottom surface thereof is disposed on both the OSP substrate 6 and the second OSP substrate 9. Thus, a portion of the bottom surface of the semiconductor chip 5 is exposed. This exposed portion includes a plurality of bond pads 1 which are wire bonded to lead fingers 3 of the OSP substrate 6 and the second OSP substrate 9, as shown in FIG. 7B. The second semiconductor chip 7 is arranged on the semiconductor chip 5. The bond pads 1 of the semiconductor chip 5 and/or the second semiconductor chip 7 may be coated in the OSP material. The first OSP substrate 6 and second OSP substrate 9 may be an integral structure separated by an aperture which exposes the portion of the bottom surface of the semiconductor chip 5.

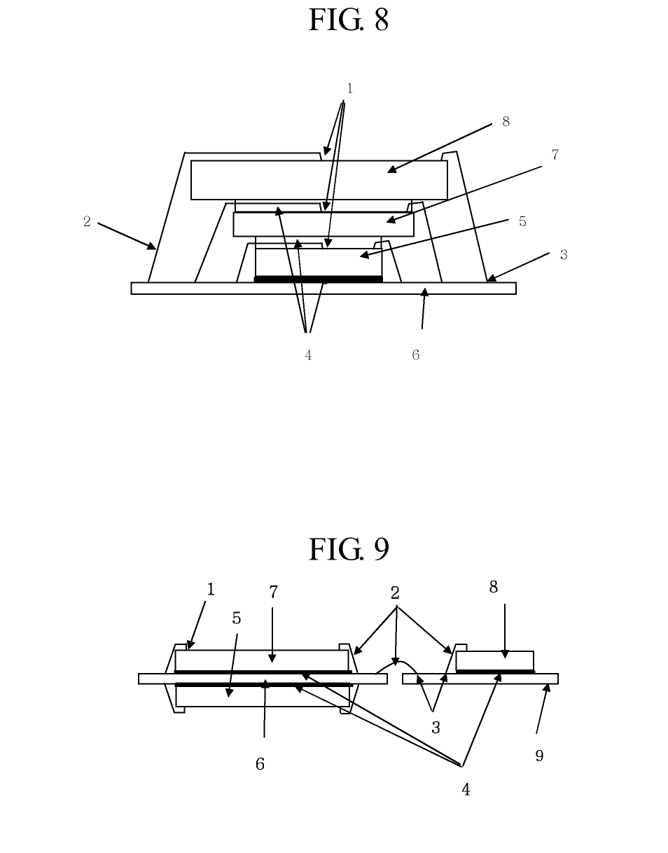

FIG. 8 illustrates a semiconductor package according to another exemplary embodiment of the present invention. As shown in FIG. 8, the semiconductor chip 5, the second semiconductor chip 7, and the third semiconductor chip 8 may be stacked vertically with descending widths approaching the OSP substrate 6. The bond pads 1 of the semiconductor chip 5, the second semiconductor chip 7 and/or the third semiconductor chip 8 may be coated in the OSP material.

FIG. 9 illustrates a semiconductor package according to another exemplary embodiment of the present invention. As shown in FIG. 9, the semiconductor chip 5 and the second semiconductor chip 7 are disposed on opposite sides of the OSP substrate 6. Also, the third semiconductor chip 8 may be disposed on the second OSP substrate 9. Copper wire bonding may electrically connect lead fingers 3 of the OSP substrate 6 and the second OSP substrate 9. The bond pads 1 of the semiconductor chip 5, the second semiconductor chip 7 and/or the third semiconductor chip 8 may be coated in the OSP material.

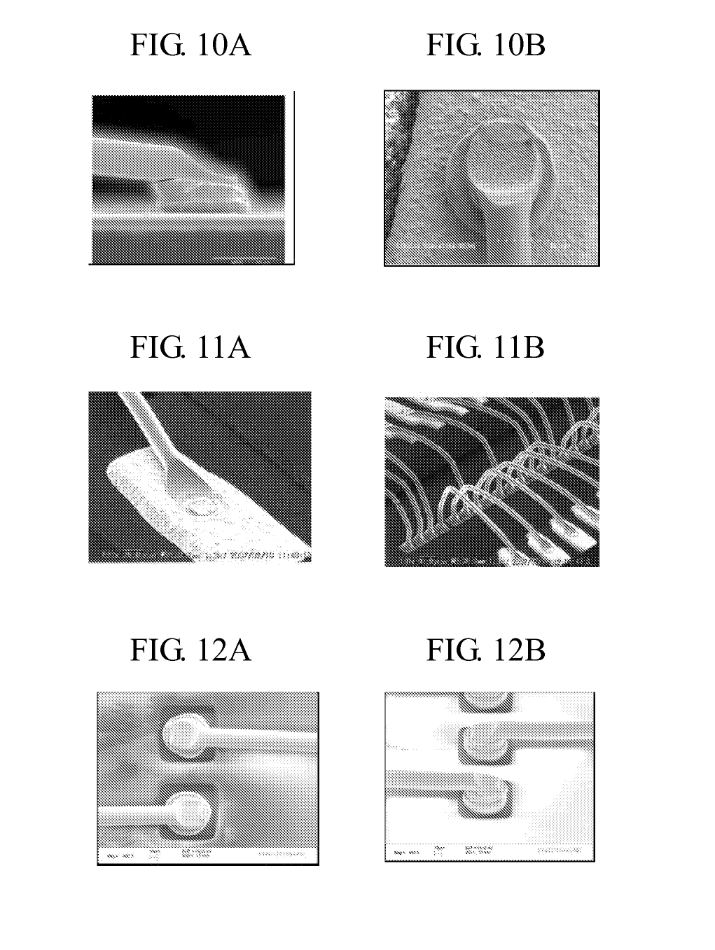

FIGS. 10-16 illustrate various bonding combinations for copper wire through OSP coating.

FIGS. 10A and 10B show alternate views of a copper Stud Bump and Stitch On Stud Bump on OSP coated copper, aluminum, and silver lead fingers of an OSP substrate.

FIGS. 11A and 11B show alternate views of a copper Stitch Bond on OSP coated copper, aluminum, and silver lead fingers of an OSP substrate.

FIGS. 12A and 12B show alternate views of a copper Stud Bump and Stitch On Stud Bump on an OSP coated copper and aluminum pads of a semiconductor chip.

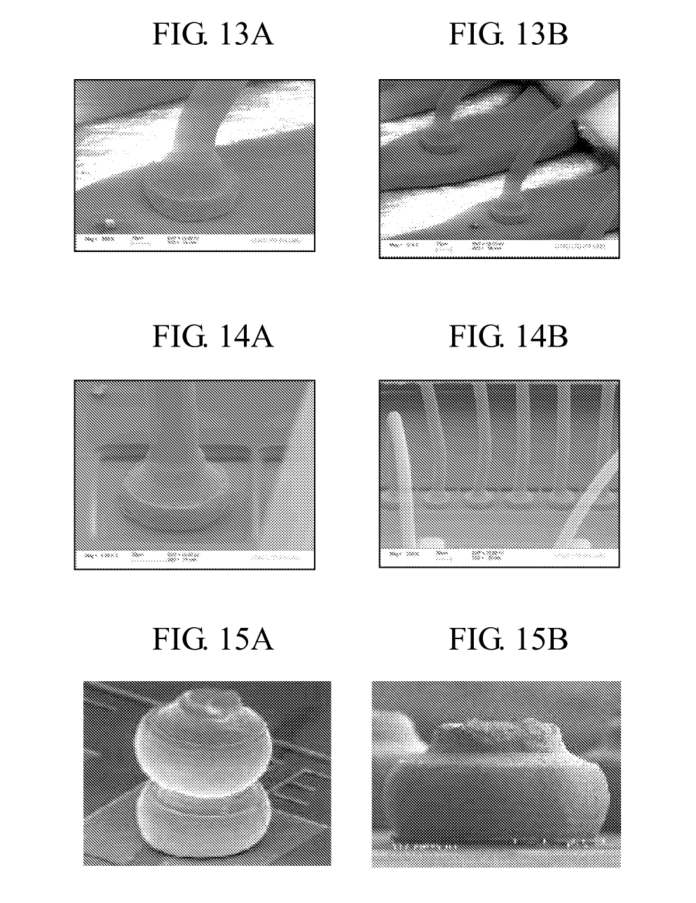

FIGS. 13A and 13B show alternate views of a copper Ball Bond on OSP coated copper and aluminum lead fingers of an OSP substrate.

FIGS. 14A and 14B show alternate views of a copper Ball Bond on OSP coated copper and aluminum pads of a semiconductor chip.

FIGS. 15A and 15B show a copper Single Stud and Stack Stud Bump on the OSP coated copper and aluminum bond pads of a semiconductor chip.

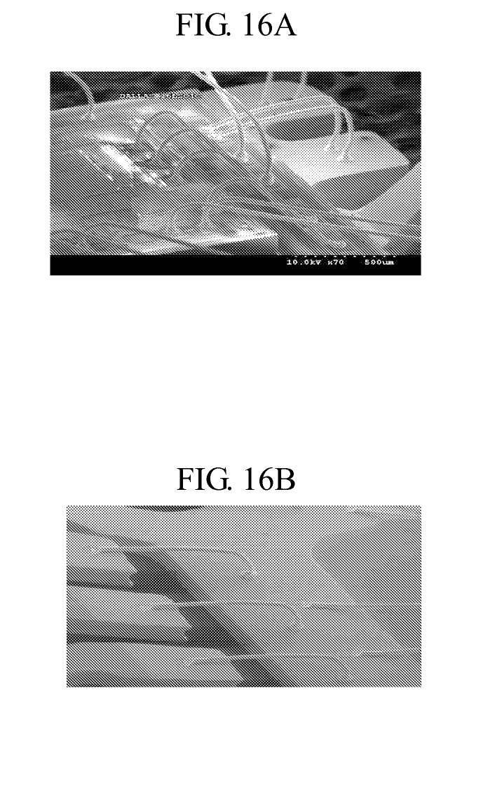

FIGS. 16A and 16B show a copper Ball Bond on OSP coated copper and aluminum bond pads as well as on OSP coated lead fingers.

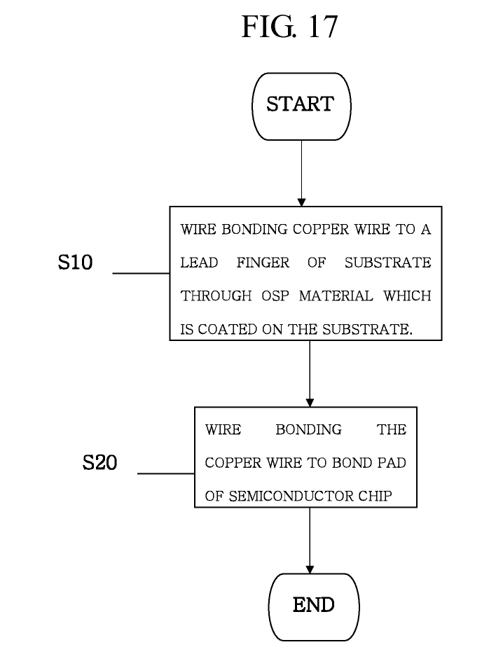

FIG. 17 shows a method of constructing a semiconductor package according to an exemplary embodiment of the present invention. In operation S10, a copper wire 2 is wire bonded to the lead finger 3 of the OSP substrate 6 through the OSP material which is coated on the OSP substrate 6. In operation S20, the copper wire 2 is wire bonded to the bond pad 1 of the semiconductor chip 5.

Using Cu wire bonding on OSP permits elimination of the process of Ni and Au coating required for Au wire bonding to achieve an acceptable electrical connection between the semiconductor chip and PCB. Cu wire bonding through OSP is not restricted to the coating of OSP on the substrate. The OSP can also be used to coat the bond pads located on the semiconductor chip, thereby allowing the connection of bond pads and PCB through Cu wires. Also, the coating of the OSP on the substrate may be formed on the lead fingers or over the partial or entire surface of the substrate.

Significantly slower inter-metallic growth in Cu wire bonding, as compared to Au wire bonding, results in lower electrical resistance and lower heat generation. This enhances the bonding reliability and device performance.

Copper materials have better conductivity as compared to gold materials, thereby increasing device power rating and improving package heat dissipation. This excellent heat dissipation characteristic can prevent the IC from overheating during electrical testing and stress environment testing.

Copper wire exhibits superior manufacturability characteristics, such as higher tensile strength and elongation as compared to gold wire, resulting in improved neck strength, improved wire sagging and wire sweep performance, excellent wire loop profile and stability for long wires during package encapsulation. It provides an excellent alternative for fine pitch package application. The fine pitch refers to the close proximity between 2 adjacent wires when the 2 bonding pads located on the semiconductor chip are very close to one another (e.g., 10 um spacing between 2 adjacent bond pads).

The OSP coating serves as an anti-oxidation layer over the chip bond pads (formed of copper, aluminum, silver, etc.) or the substrate. Furthermore, where copper (Cu) wire is bonded to Cu bond pads, owing to its monometallic system, offers better reliability as compared to inter-metallic systems such as gold wire bonded to Al bond pads.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package comprising:
a first substrate;
a first semiconductor chip attached to the first substrate, wherein at least one of the first substrate and the first semiconductor chip has an Organic Solderability Preservative (OSP) material coated on at least a portion of one surface; and
a first copper wire that is wire bonded through the OSP material to the at least one of the first substrate and the first semiconductor chip.

2. The semiconductor package according to claim 1, wherein:
the first substrate comprises a lead finger; and
the first copper wire is wire bonded to the lead finger.

3. The semiconductor package according to claim 2, wherein the lead finger is coated with the OSP material.

4. The semiconductor package according to claim 2, wherein the lead finger comprises at least one of copper, aluminum, and silver.

5. The semiconductor package according to claim 1, wherein:
the first semiconductor chip comprises a bond pad; and
the first copper wire is wire bonded to the bond pad.

6. The semiconductor package according to claim 5, wherein the bond pad is coated with the OSP material.

7. The semiconductor package according to claim 5, wherein the bond pad comprises at least one of copper, aluminum, and silver.

8. The semiconductor package according to claim 1, further comprising:
a second semiconductor chip attached to the first substrate or to the first semiconductor chip, wherein at least one of the first substrate and the second semiconductor chip has the OSP material coated on at least a portion of one surface; and
a second copper wire that is wire bonded through the OSP material to the first substrate and the second semiconductor chip.

9. The semiconductor package according to claim 8, wherein the first semiconductor chip and the second conductor chip are disposed on opposite sides of the first substrate.

10. The semiconductor package according to claim 9, further comprising:
a second substrate having the OSP material coated on at least a portion of one surface; and
a third copper wire that is wire bonded through the OSP material of the first substrate to a lead finger of the first substrate and through the OSP material of the second substrate to a lead finger of the second substrate,
wherein the lead finger comprises at least one of copper, aluminum, and silver.

11. The semiconductor package according to claim 8, wherein the second conductor chip is stacked on the first semiconductor chip.

12. The semiconductor package according to claim 11, further comprising:
a second substrate having the OSP material coated on at least a portion of one surface; and
a third copper wire that is wire bonded to the second semiconductor chip and is wire bonded through the OSP material of the second substrate to a lead finger of the second substrate,
wherein the first semiconductor chip is disposed on the first substrate and on the second substrate, and
wherein the lead finger comprises at least one of copper, aluminum, and silver.

13. The semiconductor package according to claim 8, further comprising:
a third semiconductor chip, wherein at least one of the first substrate and the third semiconductor chip has the OSP material coated on at least a portion of one surface; and
a third copper wire that is wire bonded through the OSP material to the first substrate and the third semiconductor chip,
wherein the third semiconductor chip is stacked on the second semiconductor chip, and the second semiconductor chip is stacked on the first semiconductor chip.

14. The semiconductor package according to claim 13, wherein, with respect to a cross-section view of the semiconductor package, the third semiconductor chip is wider than the second semiconductor chip, and the second semiconductor chip is wider than the first semiconductor chip.

15. The semiconductor package according to claim 13, wherein, with respect to a cross-section view of the semiconductor package, the first semiconductor chip is wider than the second semiconductor chip, and the second semiconductor chip is wider than the third semiconductor chip.

16. The semiconductor package according to claim 1, further comprising one of a Ball Bond, Stitch Bond, Ribbon Bond, Wedge Bond, and Copper Stud Bond where the copper wire is wire bonded to the substrate.

17. The semiconductor package according to claim 1, further comprising one of a Ball Bond, Stitch Bond, Ribbon Bond, Wedge Bond, and Copper Stud Bond where the copper wire is wire bonded to the semiconductor chip.

18. A method for constructing a semiconductor package, the method comprising:
(a) wire bonding one end of a copper wire to a substrate through an Organic Solderability Preservative (OSP) material which is coated on the substrate; and
(b) wire bonding an opposite end of the copper wire to a semiconductor chip.

19. The method according to claim 18, wherein:
the substrate comprises a lead finger;
(a) comprises wire bonding the copper wire through the OSP material to connect the lead finger to the semiconductor chip; and
the lead finger comprises at least one of copper, aluminum, and silver.

20. The method according to claim 19, wherein the lead finger is coated with the OSP material.

21. The method according to claim 18, wherein:
the first semiconductor chip comprises a bond pad;
(b) comprises wire bonding the copper wire to the bond pad; and
the bond pad comprises at least one of copper, aluminum, and silver.

22. The method according to claim 21, wherein the bond pad is coated with the OSP material.

23. The method according to claim 18, wherein (a) comprises forming one of a Ball Bond, Stitch Bond, Ribbon Bond, Wedge Bond, and Copper Stud Bond on the substrate.

24. The method according to claim 18, wherein (b) comprises forming one of a Ball Bond, Stitch Bond, Ribbon Bond, Wedge Bond, and Copper Stud Bond on the semiconductor chip.
